(19) United States
(12) Patent Application Publication
(10) Pub. No.: US 2013/0158914 A1
(43) Pub. Date: Jun. 20, 2013

(54) Apparatus for Measuring the State of Charge of a Battery Pack via Measuring an Open Circuit Voltage

(71) Applicants: Der-Hui Chen, Taoyuan County (TW); Ren-Her Chen, Taoyuan County (TW); Lai-Fwu You, Taoyuan County (TW)

(72) Inventors: Der-Hui Chen, Taoyuan County (TW); Ren-Her Chen, Taoyuan County (TW); Lai-Fwu You, Taoyuan County (TW)

(73) Assignee: Chung-Shan Institute of Science and Technology, Armaments, Bureau, Ministry of National Defense, Taoyuan County (TW)

(21) Appl. No.: 13/328,131

(22) Filed: Dec. 16, 2011

(51) Int. Cl. G01R 31/36; G06F 19/00

(52) U.S. Cl. 702/63

(57) ABSTRACT

Disclosed is an apparatus for measuring the state of charge of a battery pack via measuring an open circuit voltage. The apparatus includes a voltage measurement unit electrically connected to the battery pack, a current sensor electrically connected to the battery pack, a current measurement unit electrically connected to the current sensor, and a processor electrically connected to the voltage measurement unit and the current measurement unit. The processor measures the voltage and current of the battery pack via the voltage measurement unit and the current measurement unit.

### BACKGROUND OF INVENTION

1. Field of Invention

The present invention relates to an apparatus for measuring the state of charge of a battery pack and, more particularly, to an apparatus for measuring the state of charge of a battery pack via measuring an open circuit voltage.

2. Related Prior Art

There are various ways to know the state of charge (“SOC”) of a battery pack. For example, current integration (or “Coulomb integration”) can be used to estimate the SOC of a battery pack. However, current integration is vulnerable to accumulated errors for a long period of time. Hence, current integration is often corrected by measuring an open circuit voltage (“OCV”). Examples for measuring the SOC of a battery pack based on current integration can be seen in US2006202663A1, US2008094031A1 and US2006261782A1.

To measure the OCV accurately, the battery pack has to rest for hours. Referring to FIG. 7, voltage and current versus time are shown. As the battery pack discharges at a current I, the voltage of the battery pack continues to drop. When the battery pack stops discharging, i.e., the current is zero, the voltage of the battery pack starts to rise. Because of chemical balance, in the beginning, the voltage of the battery pack rises fast. Then, the rising of the voltage of the battery pack slows down. Finally, the voltage of the battery pack reaches a stable value, and such a value can be measured and deemed the OCV. By mapping the measured value of the voltage to a voltage versus SOC relationship, the SOC can be learned. It however takes quite some time for the battery pack to reach the OCV, and this is inconvenient.

The present invention is therefore intended to obviate or at least alleviate the problems encountered in prior art.

### SUMMARY OF INVENTION

It is the primary objective of the present invention to provide an apparatus for measuring the state of charge of a battery pack via measuring an open circuit voltage.

To achieve the foregoing objective, the apparatus includes a voltage measurement unit electrically connected to the battery pack, a current sensor electrically connected to the battery pack, a current measurement unit electrically connected to the current sensor, and a processor electrically connected to the voltage measurement unit and the current measurement unit. The processor measures the voltage and current of the battery pack via the voltage measurement unit and the current measurement unit.

In an aspect, the battery pack includes at least one Li—H battery.

In another aspect, to measure the voltage and current of the battery pack, the current from the battery pack is measured. The state of charge of the battery pack is calculated by current integration. It is determined whether the current is zero. The process returns to the measurement of the current from the battery pack if not. The voltage of the battery pack is measured and referred to as the first voltage if so. Then, the voltage of the battery pack is measured and referred to as the second voltage after the battery pack rests for a period of time. The voltage difference between the first and second voltages is calculated. It is determined whether the absolute value of the voltage difference is smaller than or equal to the threshold voltage. The process returns to the step of measuring the current if not, or the second voltage is referred to as the similar stable voltage if so. A predicted open circuit voltage of the battery pack is calculated. The state of charge is calculated by mapping the predicted open circuit voltage to the relationship between the open circuit voltage and the state of charge.

In another aspect, the predicted open circuit voltage is the similar stable voltage plus an average voltage offset.

In another aspect, to measure the voltage and current of the battery pack, the current from the battery pack is measured. The state of charge of the battery pack is calculated by current integration. It is determined whether the current is zero. The process returns to the measurement of the current from the battery pack if not or the voltage of the battery pack is measured and referred to as the first voltage if so. Then, the voltage of the battery pack is measured and referred to as the second voltage after the battery pack rests for a period of time. The voltage difference between the first and second voltages is calculated. It is determined whether the absolute value of the voltage difference is smaller than or equal to the threshold voltage. The process returns to the step of measuring the current if not, or the second voltage is referred to as the similar stable voltage if so. The state of charge is obtained by mapping the predicted open circuit voltage to the relationship between the similar stable voltage and the state of charge.

In another aspect, to measure the similar stable voltage, the battery pack discharges at a constant current to reduce the state of charge to a predetermined percentage after the recharging of the battery pack is done. The battery pack rests for some time so that the similar stable voltage can be measured. The foregoing steps are repeated so that the SOC becomes zero, thus obtaining a relationship between the similar stable voltage and the state of charge of the battery pack.

Other objectives, advantages and features of the present invention will be apparent from the following description referring to the attached drawings.

### BRIEF DESCRIPTION OF DRAWINGS

The present invention will be described via detailed illustration of the preferred embodiment vs. the prior art referring to the drawings wherein:

FIG. 1 is a perspective view of apparatus for measuring the state of charge of a battery pack via measuring an open circuit voltage according to the preferred embodiment of the present invention;

FIG. 2 shows first and second voltages and their difference vs. time in the apparatus shown in FIG. 1;

FIG. 3 shows OCV and Vss vs. SOC in the apparatus shown in FIG. 1;

FIG. 4 shows OCV vs. SOC in the apparatus shown in FIG. 1;

FIG. 5 is a flow chart of a first process executed in the apparatus shown in FIG. 1;

FIG. 6 is a flow chart of a second process executed in the apparatus shown in FIG. 1; and

FIG. 7 shows voltage and current vs. time in the prior art.

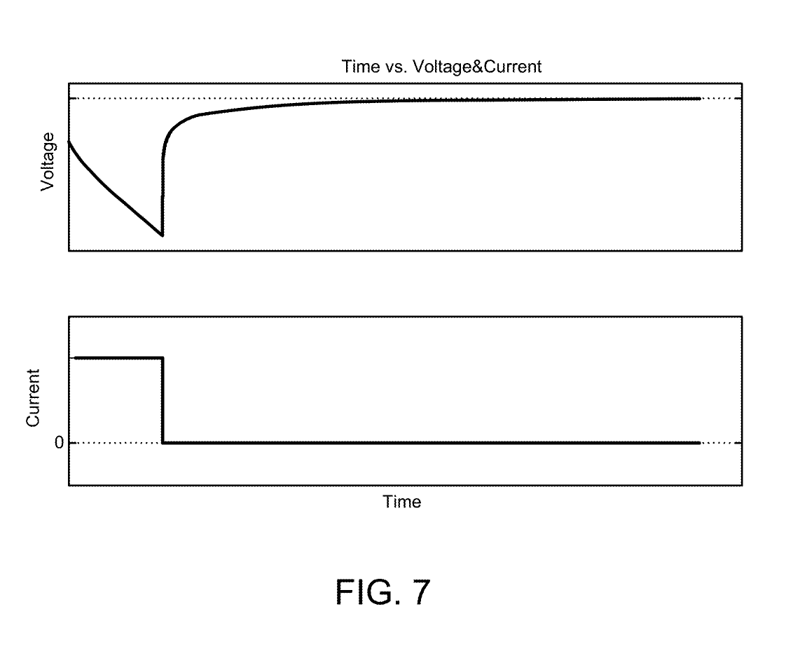

### DETAILED DESCRIPTION OF PREFERRED EMBODIMENT

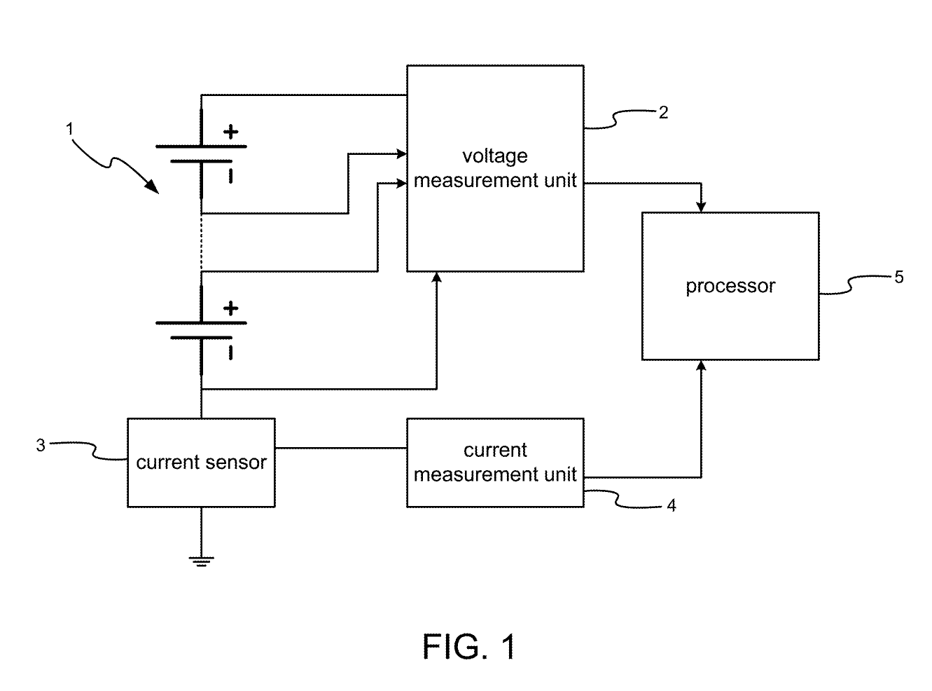

Referring to FIG. 1, disclosed is an apparatus for measuring the state of charge (“SOC”) of a battery pack 1 via measuring an open circuit voltage according to the preferred embodiment of the present invention. The apparatus includes a voltage measurement unit 2, a current sensor 3, a current measurement unit 4 and a processor 5. The battery pack 1 may include at least one Li—H battery. The voltage measurement unit 2 is electrically connected to the battery pack 1. The current sensor 3 is electrically to the battery pack 1. The current measurement unit 4 is electrically connected to the current sensor 3. The processor 5 is electrically connected to the voltage measurement unit 2 and the current measurement unit 4. The processor 5 measures the voltage and current of the battery pack 1 via the voltage measurement unit 2 and the current measurement unit 4.

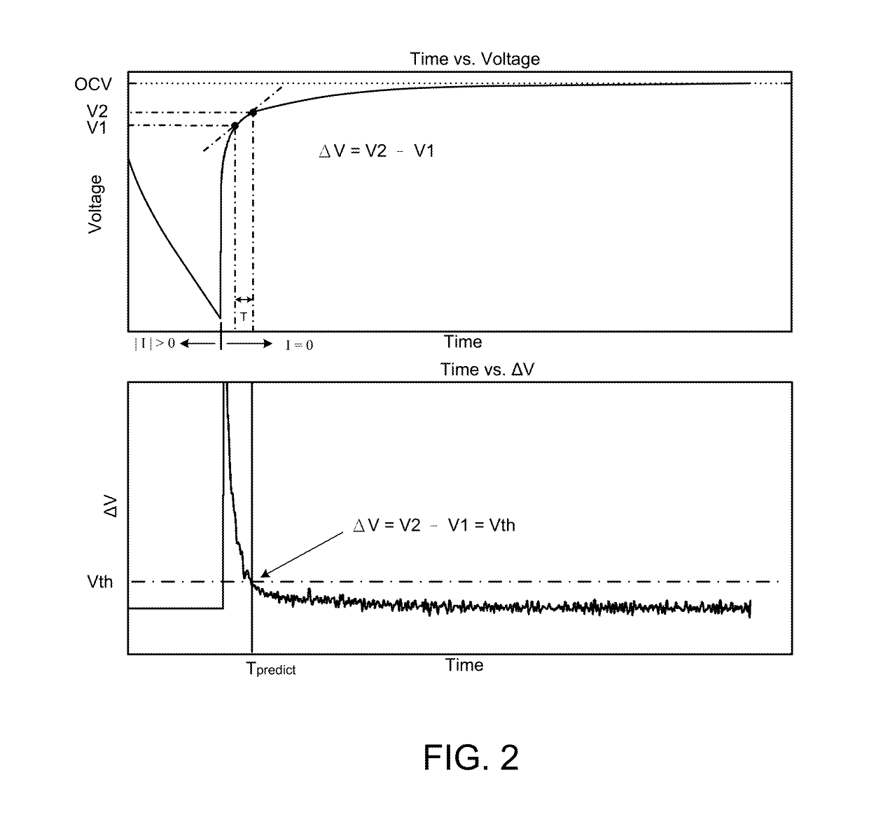

In the present invention, the similar stable voltage Vss is used as a novel parameter. Referring to FIG. 2, as the battery pack 1 rests (the current is zero) after discharging, the voltage of the battery pack 1 is measured and referred to as the first voltage V1. After a period of time T, the voltage of the battery pack 1 is measured again and referred to as the second voltage V2. Then, the voltage difference ΔV between the first and second voltages V1 and V2 is calculated (ΔV=V2−V1), and it is determined whether the absolute value of the voltage difference (|ΔV|) is smaller than or equal to the threshold voltage Vₜₕ. If so, the second voltage V2 is referred to as the similar stable voltage Vss, and the time is referred to as predicted time T_{predict}. Otherwise, the process returns to the step of measuring the current of the battery pack 1.

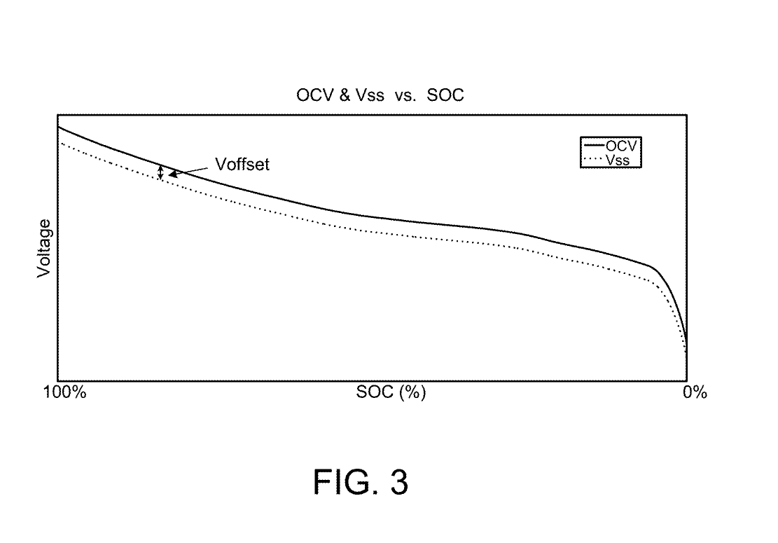

To measure the similar stable voltage Vss, after the battery pack 1 is fully charged, the battery pack 1 discharges at a constant current I so that the SOC is reduced to a predetermined percentage. Then, the battery pack 1 rests for some time so that the similar stable voltage Vss can be measured. The process is repeated so that the battery pack 1 finishes the discharging. Thus, obtained is a relationship between the similar stable voltage Vss and the SOC of the battery pack as shown in FIG. 3. The difference between the similar stable voltage Vss and the OCV is referred to as the voltage offset Voffset, and both of the similar stable voltage Vss and the voltage offset Voffset are functions of the SOC of the battery pack 1.

After tests, no matter how large the current I from the battery pack 1 is, the relationship between the similar stable voltage Vss and the SOC of the battery pack 1 is substantially constant. That is, no matter how large the current I is, the similar stable voltage Vss is determined by the SOC. In other words, the similar stable voltage Vss is not a function of the current I but a function of the SOC. Therefore, the voltage offset Voffset is not a function of the current I, but a function of the SOC.

Furthermore, the voltage offset Voffset remains unchanged regardless of the SOC of the battery pack 1. Therefore, and an average voltage offset V̅o̅f̅f̅s̅e̅t̅ of battery pack 1 can be calculated.

In use, the SOC of the battery pack 1 may be determined in either of the following measures.

### Measure 1

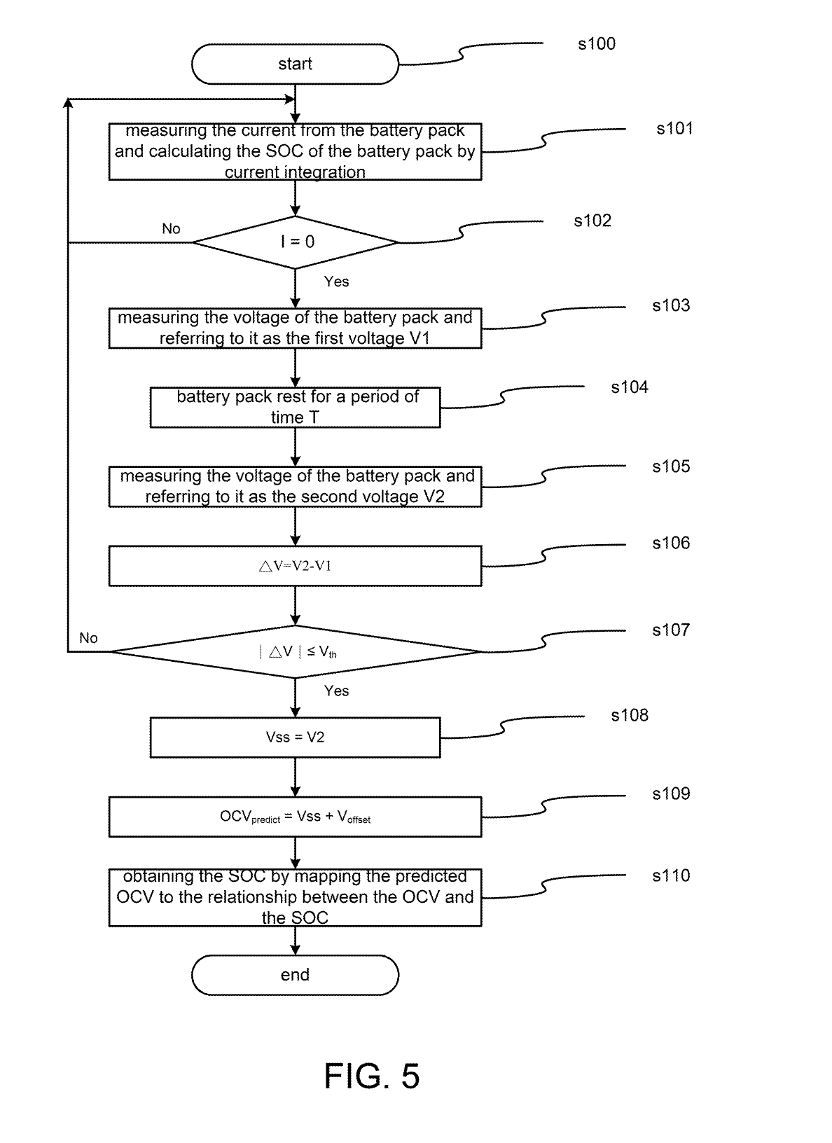

Referring to FIG. 5, at s100, the process is initiated.

At s101, the current I from the battery pack 1 is measured, and the SOC of the battery pack 1 is calculated by current integration.

At s102, it is determined whether the current I is zero. The process goes to S103 if so or returns to s101 if not.

At s103, the voltage of the battery pack 1 is measured and referred to as the first voltage V1.

At s104, the battery pack 1 rests for a period of time T.

At s105, the voltage of the battery pack 1 is measured and referred to as the second voltage V2.

At s106, the voltage difference ΔV between the first and second voltages V1 and V2 is calculated (ΔV=V2−V1).

At s107, it is determined whether the absolute value of the voltage difference is smaller than or equal to the threshold voltage Vₜₕ. The process goes to s108 if so or returns to s101 if not.

At s108, the second voltage V2 is referred to as the similar stable voltage Vss.

At s109, the predicted OCV of the battery pack 1 is calculated (OCV_{predict}=Vss+ V̅o̅f̅f̅s̅e̅t̅).

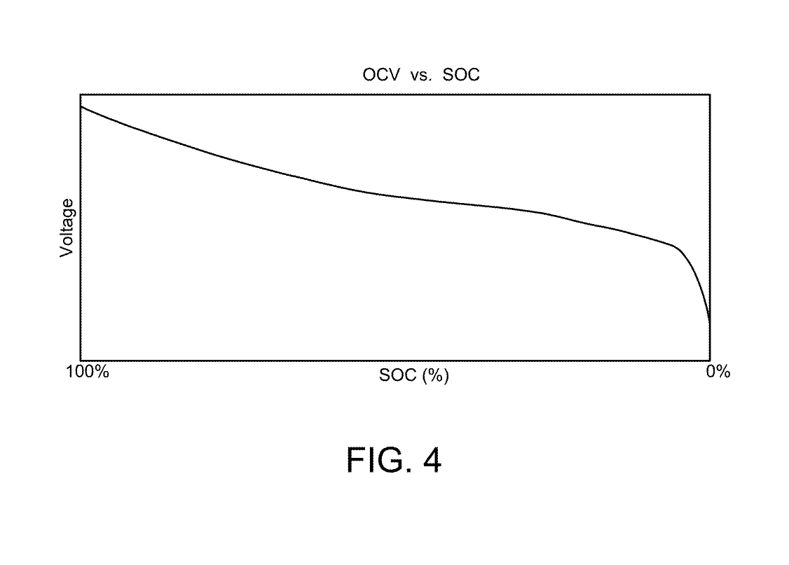

At s110, the SOC is obtained by mapping the OCV_{predict} to the relationship between the OCV and the SOC referring to FIG. 4. The SOC obtained in this manner is more accurate than the SOC calculated by the current integration, and can therefore be used for correction.

### Measure 2

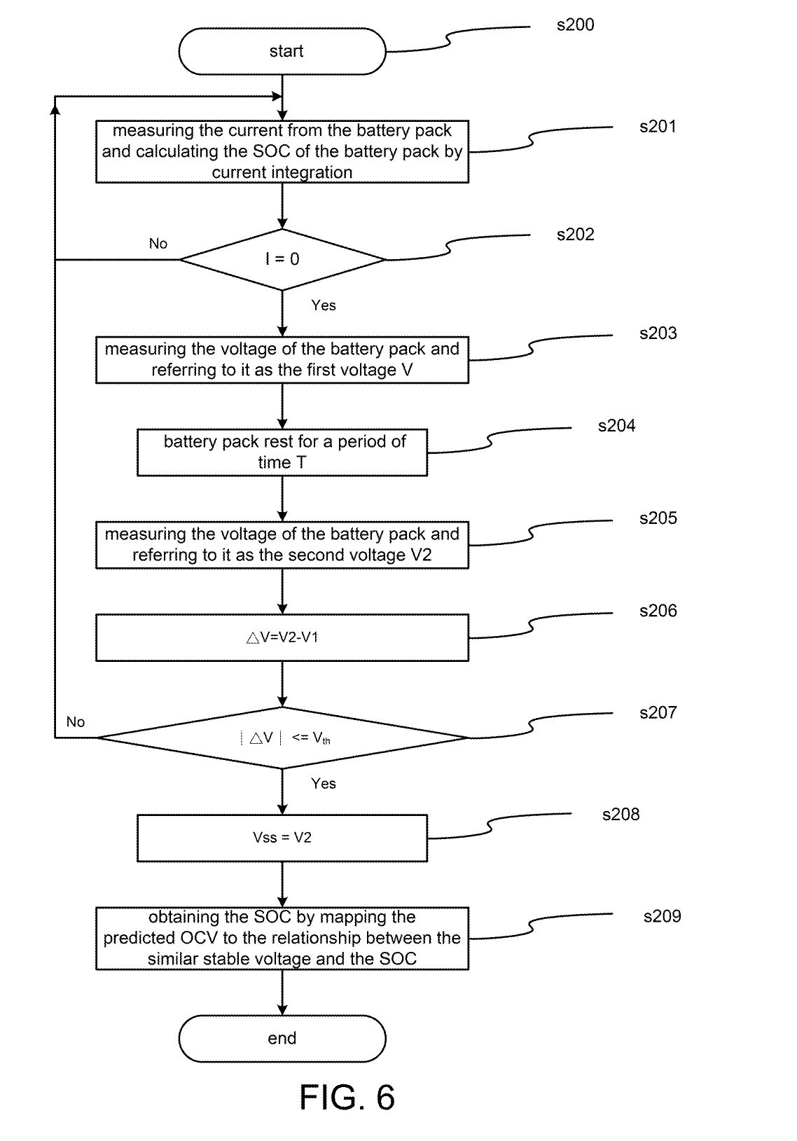

Referring to FIG. 6, at s200, the process is initiated.

At s201, the current I from the battery pack 1 is measured, and the SOC of the battery pack 1 is calculated by current integration.

At s202, it is determined whether the current I is zero. The process goes to S203 if so or returns to s201 if not.

At s203, the voltage of the battery pack 1 is measured and referred to as the first voltage V1.

At s204, the battery pack 1 rests for a period of time T.

At s205, the voltage of the battery pack 1 is measured and referred to as the second voltage V2.

At s206, the voltage difference ΔV between the first and second voltages V1 and V2 is calculated (ΔV=V2−V1).

At s207, it is determined whether the absolute value of the voltage difference is smaller than or equal to the threshold voltage Vₜₕ. The process goes to s208 if so or returns to s201 if not.

At s208, the second voltage V2 is referred to as the similar stable voltage Vss.

At s209, the SOC is obtained by mapping the OCV_{predict} to the relationship between the similar stable voltage Vss and the SOC as shown in FIG. 3. The SOC obtained in this manner is more accurate than the SOC calculated by the current integration, and can therefore be used for correction.

Conventionally, the battery pack 1 must rest for a period of time T_{OCV} so that the OCV can be measured and used to predict the SOC of the battery pack 1. With the present invention, the battery pack 1 only has to rest for T_{predict}. In practice, the battery pack 1 has to rest for only minutes, not hours, and the tolerance is less than 3%. The present invention is not only useful and effective for the discharging from the battery pack 1 but also the recharging of the battery pack 1, yet the parameter for the discharging is different from the parameter for the recharging.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. An apparatus for measuring the state of charge of a battery pack via measuring an open circuit voltage including:
a voltage measurement unit 2 electrically connected to the battery pack 1;
a current sensor 3 electrically connected to the battery pack 1;
a current measurement unit 4 electrically connected to the current sensor 3; and
a processor 5 electrically connected to the voltage measurement unit 2 and the current measurement unit 4, wherein the processor 5 measures the voltage and current of the battery pack 1 via the voltage measurement unit 2 and the current measurement unit 4.

2. The apparatus for measuring the state of charge of a battery pack via measuring an open circuit voltage according to claim 1, wherein the battery pack 1 includes at least one Li—H battery.

3. The apparatus for measuring the state of charge of a battery pack via measuring an open circuit voltage according to claim 1, wherein the processor 5 measures the voltage and current of the battery pack 1 in a method including the steps of:
measuring the current from the battery pack 1;
calculating the state of charge of the battery pack 1 by current integration;
determining whether the current is zero and returning to the step of measuring the current from the battery pack 1 if not;
measuring the voltage of the battery pack 1 and referring to the measured value as the first voltage if so;
making the battery pack 1 to rest for a period of time;
measuring the voltage of the battery pack 1 and referring to the measured value as the second voltage;
calculating the voltage difference between the first and second voltages;
determining whether the absolute value of the voltage difference is smaller than or equal to the threshold voltage and returning to the step of measuring the current if not;
referring to the second voltage as the similar stable voltage if so;
calculating a predicted open circuit voltage of the battery pack 1; and
obtaining the state of charge by mapping the predicted open circuit voltage to the relationship between the open circuit voltage and the state of charge.

4. The apparatus for measuring the state of charge of a battery pack via measuring an open circuit voltage according to claim 3, wherein the predicted open circuit voltage is the similar stable voltage plus an average voltage offset.

5. The apparatus for measuring the state of charge of a battery pack via measuring an open circuit voltage according to claim 1, wherein the processor 5 measures the voltage and current of the battery pack 1 in a method including the steps of:
measuring the current from the battery pack 1;
calculating the state of charge of the battery pack 1 by current integration;
determining whether the current is zero and returning to the step of measuring the current from the battery pack 1 if not;
measuring the voltage of the battery pack 1 and referring to the measured value as the first voltage if so;
making the battery pack 1 rest for a period of time;
measuring the voltage of the battery pack 1 and referring to the measured value as the second voltage;
calculating the voltage difference between the first and second voltages;
determining whether the absolute value of the voltage difference is smaller than or equal to the threshold voltage and returning to the step of measuring the current if not;
referring to the second voltage as the similar stable voltage if so; and
obtaining the state of charge by mapping the predicted open circuit voltage to the relationship between the similar stable voltage and the state of charge.

6. The apparatus for measuring the state of charge of a battery pack via measuring an open circuit voltage according to claim 5, wherein the similar stable voltage is measured in a method including the steps of:
discharging a constant current from the battery pack 1 to reduce the state of charge to a predetermined percentage after the recharging of the battery pack 1 is done;
making the battery pack 1 rest restes for some time so that the similar stable voltage can be measured;
repeating the foregoing steps process so that the discharging by the battery pack 1 is done, thus obtaining a relationship between the similar stable voltage and the state of charge the battery pack 1.
